(19) United States
(12) Patent Application Publication
(10) Pub. No.: US 2011/0249696 A1
(43) Pub. Date: Oct. 13, 2011

(54) Laser diode

(75) Inventors: Yuji Masui, Miyagi (JP); Takahiro Arakida, Kanagawa (JP); Kayoko Kikuchi, Kanagawa (JP); Terukazu Naruse, Miyagi (JP); Koichi Kondo, Kanagawa (JP); Naoki Jogan, Kanagawa (JP)

(73) Assignee: Sony Corporation, Tokyo (JP)

(21) Appl. No.: 13/064,524

(22) Filed: Mar. 30, 2011

(30) Foreign Application Priority Data
Apr. 8, 2010 (JP) 2010-089841

(51) Int. Cl. H01S 5/00

(52) U.S. Cl. 372/46.01

(57) ABSTRACT

There is provided a laser diode capable of setting a mesa diameter small without use of a method which loses reliability of a device, and is not easily controlled. The laser diode includes: a columnar mesa including a first multilayer film reflecting mirror, an active layer, and a second multilayer film reflecting mirror in this order, including an oxide confined layer having an unoxidized region in middle of a plane, and having a cross-sectional shape in a plane direction different from a cross-sectional shape of the unoxidized region in a plane direction; and a plurality of metal electrodes formed in regions on a top face of the mesa not facing the unoxidized region.

### BACKGROUND OF THE INVENTION

1. Field of the Invention

The present invention relates to a laser diode emitting laser light in a stacking direction.

2. Description of the Related Art

In a vertical cavity surface emitting laser (VCSEL), a columnar mesa in which a lower DBR layer, a lower spacer layer, an active layer, an upper spacer layer, an upper DBR layer, and a contact layer are stacked in this order on a substrate is typically provided. A current confining layer having a structure in which a current injection region is narrowed for increasing the current injecting efficiency to the active layer, and reducing a threshold current is provided in one of the lower DBR layer and the upper DBR layer. An electrode is provided on each of the top face of the mesa, and the rear face of the substrate. In this semiconductor laser, a current injected from the electrode is confined by the current confining layer and then injected into the active layer, and light emission is thereby generated by recombination of electrons and holes. This light is reflected at the lower DBR layer and the upper DBR layer, laser oscillation is generated at a predetermined wavelength, and the light is emitted as laser light from the top face of the mesa.

In the VCSEL described above, the laser oscillation by a low threshold current of 1 mA or lower is possible, and the high-speed modulation with low power consumption is possible. Thus, the VCSEL is used as a low-cost light source for optical communication.

### SUMMARY OF THE INVENTION

To perform the high-speed modulation, it is necessary to make a parasitic capacity of a device small. In the VCSEL, for example, it is possible to suppress the capacity of the current confining layer and a p-n junction low by reducing the mesa diameter. However, the mesa diameter is limited by the size (width) and the position accuracy of the electrode formed on the top face of the mesa.

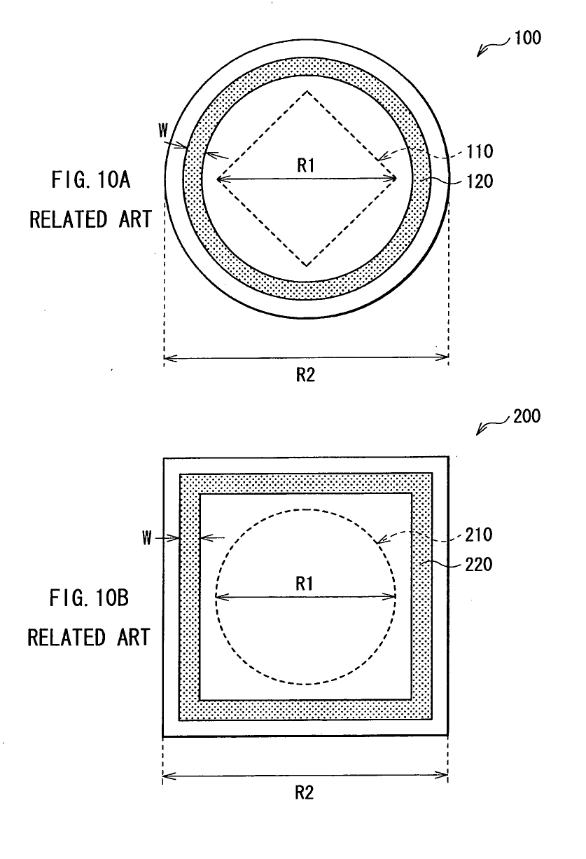

FIGS. 10A and 10B illustrate an example of the top face structure of mesas 100 and 200. The broken lines in FIGS. 10A and 10B illustrate current injection regions (unoxidized regions) 110 and 210 of the current confining layers (not illustrated in the figure) provided in the mesas 100 and 200. On the top faces of the mesas 100 and 200, ring shaped electrodes 120 and 220 are provided so as to avoid regions facing the current injection regions 110 and 210. At this time, if a diameter R1 of each of the current injection regions 110 and 210 is 10 μm, a width W of the electrode 120 is 1 μm, and a position accuracy AD of the electrode 120 is ±2 μm, a diameter R2 of the mesa 100 is obtained by the following formula.

R2=R1+W×2+(ΔD+ΔD)×2=10+1×2+(2+2)×2=20 μm

For example, one solution to such a limitation is that the current confining layer is increased in thickness or multilayered, as described in Japanese Unexamined Patent Publication No. 2003-168845. By making the current confining layer thick or multilayered, it is possible to insulate a side face of the mesa. As a result, it is actually possible to reduce the diameter of the mesa. However, when the current confining layer is increased in thickness, high strain stress is generated inside the mesa, and there is a risk that reliability of a device is lost. Further, in the case where the current confining layer is multilayered, the oxidation rate of each layer is not easily controlled, and there is an issue that it is not easy to manufacture an intended structure.

In view of the foregoing, it is desirable to provide a laser diode capable of setting a mesa diameter small without use of a method which loses reliability of a device, and is not easily controlled.

According to an embodiment of the present invention, there is provided a first laser diode including: a columnar mesa including a first multilayer film reflecting mirror, an active layer, and a second multilayer film reflecting mirror in this order, and including an oxide confined layer having an unoxidized region in middle of a plane. The laser diode includes a plurality of metal electrodes formed in regions on a top face of the mesa not facing the unoxidized region. In the laser diode, a cross-sectional shape of the mesa in a plane direction is different from a cross-sectional shape of the unoxidized region in a plane direction.

In the first laser diode according to the embodiment of the present invention, the plurality of metal electrodes are provided in the regions on the top face of the mesa not facing the unoxidized region. Thereby, a diameter of the mesa having the cross-sectional shape different from the cross-sectional shape of the unoxidized region is reduced. As a result, in the case where the region on the top face of the mesa not facing the unoxidized region is substantially partitioned into a plurality of regions, it is possible to arrange each metal electrode in that region (empty space), even if a position accuracy of the metal electrode is the same as that of related art.

According to another embodiment of the present invention, there is provided a second laser diode including: a columnar mesa including a first multilayer film reflecting mirror, an active layer, and a second multilayer film reflecting mirror in this order, and including an oxide confined layer having an unoxidized region in middle of a plane. The laser diode includes a circular metal electrode formed in a region on a top face of the mesa not facing the unoxidized region. In the laser diode, a cross-sectional shape of the mesa in a plane direction is different from a cross-sectional shape of the unoxidized region in a plane direction. Further, when a gravity point (center) of the metal electrode in a plane, and a gravity point (center) of the unoxidized region in a plane are superposed on each other in the same plane, a gap between an edge of the metal electrode, and an edge of the unoxidized region is uniform.

In the second laser diode according to the embodiment of the present invention, when the gravity point (center) of the circular metal electrode in the plane, and the gravity point (center) of the unoxidized region in the plane are superposed on each other in the same plane, the gap between the edge of the metal electrode, and the edge of the unoxidized region is uniform. Thereby, a diameter of the mesa having the cross-sectional shape different from the cross-sectional shape of the unoxidized region is reduced. As a result, in the case where the region on the top face of the mesa not facing the unoxidized region is substantially partitioned into a plurality of regions, it is possible to arrange the circular metal electrode in that region (empty space), even if a position accuracy of the metal electrode is the same as that of related art.

According to the first laser diode of the embodiment of the present invention, it is possible to arrange each metal electrode in the region on the top face of the mesa not facing the unoxidized region, even if the position accuracy of the metal electrode is the same as that of related art. Thus, it is possible to make the mesa diameter smaller compared with a case where a single metal electrode is provided on the top face of the mesa. Further, because the plurality of electrodes are provided on the top face of the mesa, reliability of a device is not lost. Therefore, it is possible to make the mesa diameter smaller without use of a method which loses the reliability of the element, and is not easily controlled.

According to the second laser diode of the embodiment of the present invention, it is possible to arrange the circular metal electrode in the region on the top face of the mesa not facing the unoxidized region, even if the position accuracy of the metal electrode is the same as that of related art. Thus, it is possible to make the mesa diameter smaller compared with a case where the single metal electrode is provided on the top face of the mesa. Further, because the plurality of electrodes are provided on the top face of the mesa, the reliability of the device is not lost. Therefore, it is possible to make the mesa diameter smaller without use of the method which loses the reliability of the element, and is not easily controlled.

Other and further objects, features and advantages of the invention will appear more fully from the following description.

BRIEF DESCRIPTION OF THE DRABLADE SECTIONS

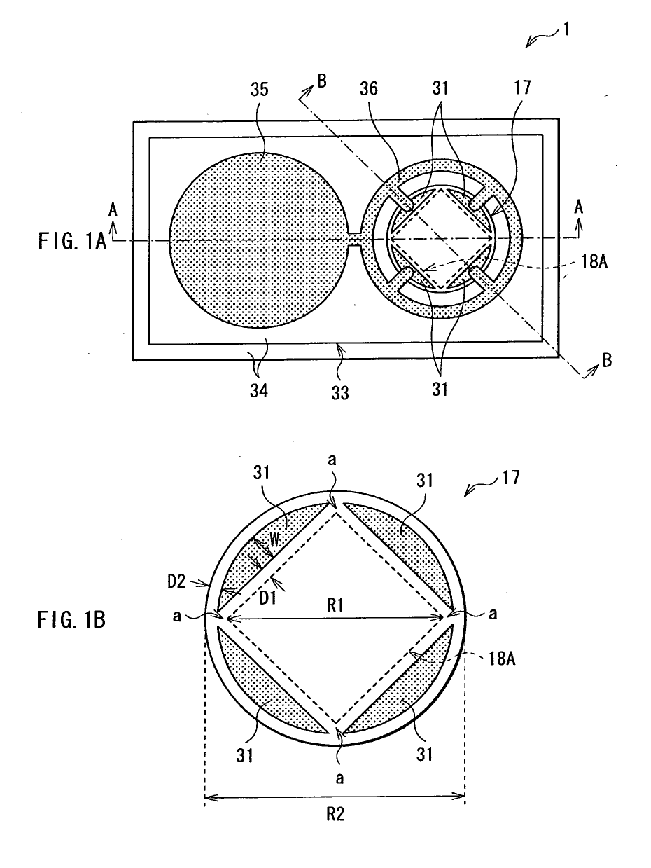

FIGS. 1A and 1B are top views of a VCSEL according to an embodiment of the present invention.

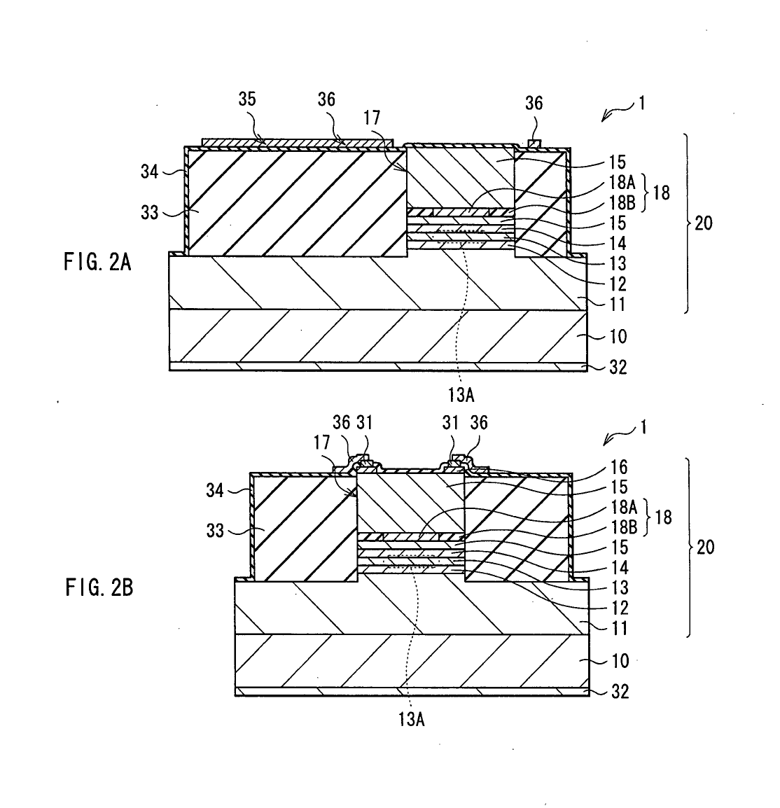

FIGS. 2A and 2B are cross-sectional views of the laser diode of FIG. 1.

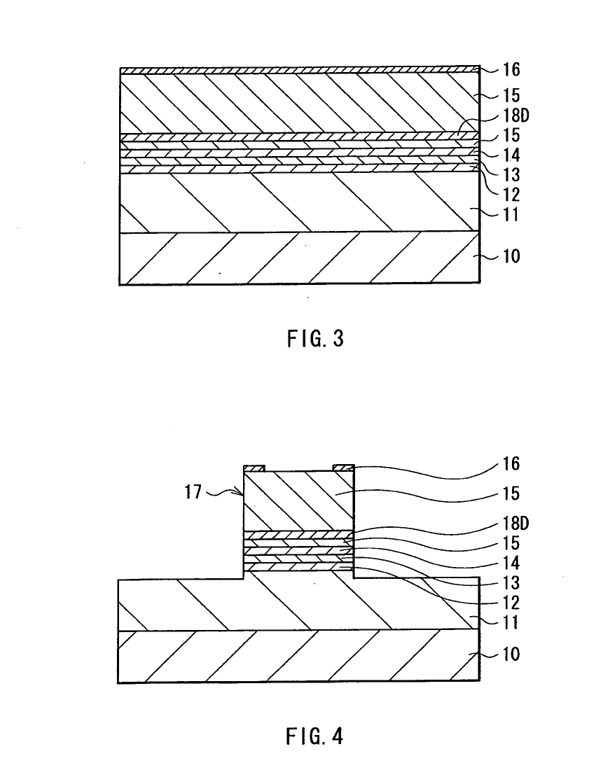

FIG. 3 is a cross-sectional view for explaining an example of a manufacturing process of the laser diode of FIG. 1.

FIG. 4 is a cross-sectional view for explaining a step subsequent to FIG. 3.

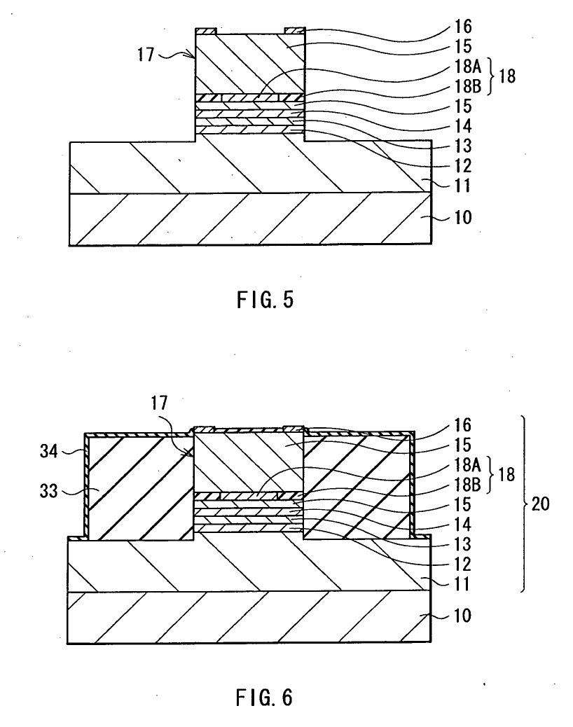

FIG. 5 is a cross-sectional view for explaining a step subsequent to FIG. 4.

FIG. 6 is a cross-sectional view for explaining a step subsequent to FIG. 5.

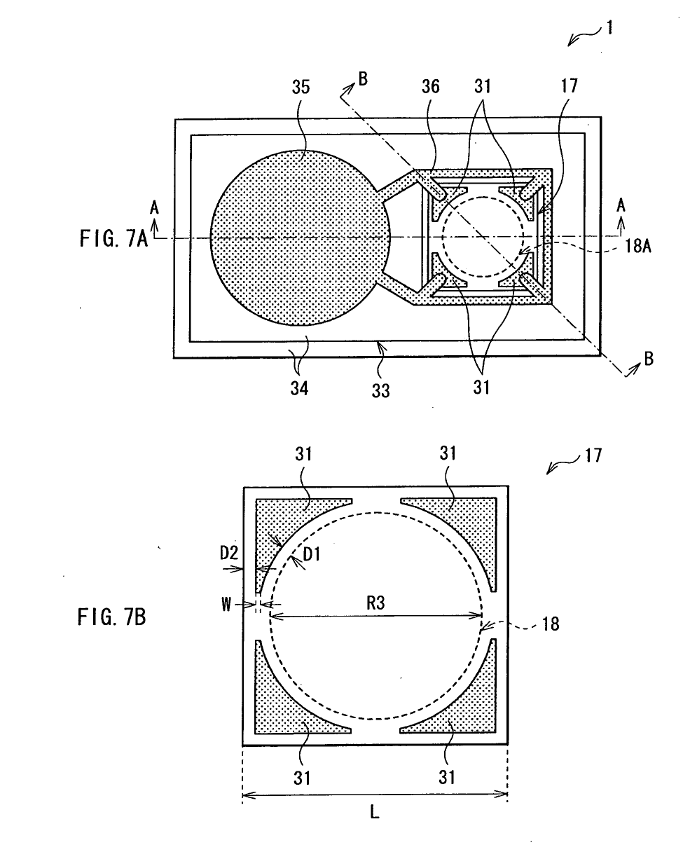

FIGS. 7A and 7B are top views of a modification of the laser diode of FIG. 1.

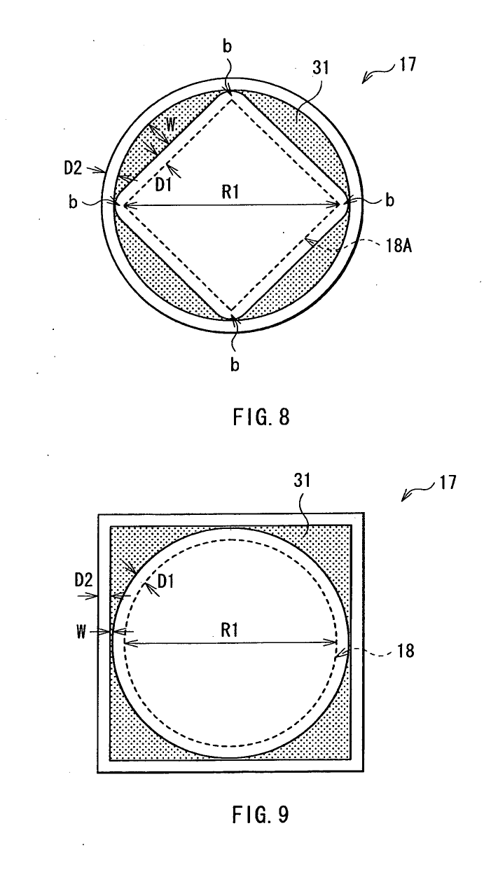

FIG. 8 is a top view of another modification of the laser diode of FIG. 1.

FIG. 9 is a top view of still another modification of the laser diode of FIG. 1.

FIGS. 10A and 10B are top views of a VCSEL of related art.

### DETAILED DESCRIPTION OF THE PREFERRED EMBODIMENT

An embodiment of the present invention will be hereinafter described in detail with reference to the drawings. In addition, description will be given in the following order.

### 1. Embodiment (FIGS. 1A and 1B to 6)

Example in which a rectangular current injection region is provided in a cylinder mesa

### 2. Modification (FIGS. 7A and 7B to 9)

Example in which a circular current injection region is provided in a prismatic mesa

### 3. Related Art (FIG. 10)

Example in which a circular current injection region is provided in a cylinder mesa

Example in which a rectangular current injection region is provided in a prismatic mesa

### Embodiment

FIGS. 1A and 1B illustrate an example of the top face structure of a VCSEL 1 according to an embodiment of the present invention. FIG. 2A illustrates an example of the cross-sectional structure of the laser diode 1 of FIGS. 1A and 1B in the direction of arrow A-A. FIG. 2B illustrates an example of the cross-sectional structure of the laser diode 1 of FIGS. 1A and 1B in the direction of arrow B-B. In addition, FIGS. 1A and 1B, and 2A and 2B are schematic views, and are different from actual dimensions.

The laser diode 1 of this embodiment includes a semiconductor layer 20 in which a lower DBR layer 11, a lower spacer layer 12, an active layer 13, an upper spacer layer 14, an upper DBR layer 15, and a contact layer 16 are stacked in this order on one face side of a substrate 10. An upper part of the semiconductor layer 20, specifically, an upper part of the lower DBR layer 11, the lower spacer layer 12, the active layer 13, the upper spacer layer 14, the upper DBR layer 15, and the contact layer 16 correspond to a columnar mesa 17. In this embodiment, the lower DBR layer 11 corresponds to a specific example of “first multilayer film reflecting mirror” of the present invention. The upper DBR layer 15 corresponds to a specific example of “second multilayer film reflecting mirror” in the present invention.

The substrate 10 is, for example, an n-type GaAs substrate. Examples of an n-type impurity include silicon (Si) or selenium (Se). The semiconductor layer 20 is, for example, constituted of an AlGaAs compound semiconductor. The AlGaAs compound semiconductor means a compound semiconductor containing at least aluminum (Al) and gallium (Ga) in group 3B elements of the short-form periodic table, and at least arsenic (As) in group 5B elements of the short-form periodic table.

The lower DBR layer 11 is formed by alternately stacking a low-refractive index layer (not illustrated in the figure) and a high-refractive index layer (not illustrated in the figure). The low-refractive index layer is, for example, constituted of an n-type Alₓ₁Ga₁₋ₓ₁As (0<x1<1) with a thickness of λ₀/4n₁ (λ₀ is the oscillation wavelength, and n₁ is the refractive index). The high-refractive index layer is, for example, constituted of an n-type Alₓ₂Ga₁₋ₓ₂As (0<x2<x1) with a thickness of λ₀/4n₂ (n₂ is the refractive index).

The lower spacer layer 12 is, for example, constituted of an undoped Alₓ₃Ga₁₋ₓ₃As (0<x3<1). The active layer 13 is, for example, constituted of an undoped Alₓ₄Ga₁₋ₓ₄As (0<x4<1). In the active layer 13, a region facing a current injection region 18A which will be described later is a light emitting region 13A. The upper spacer layer 14 is, for example, constituted of an undoped Alₓ₅Ga₁₋ₓ₅As (0≦x5<1). The lower spacer layer 12, the active layer 13, and the upper spacer layer 14 may contain a p-type impurity. Examples of the p-type impurity include zinc (Zn), magnesium (Mg), and beryllium (Be).

The upper DBR layer 15 is formed by alternately stacking a low-refractive index layer (not illustrated in the figure) and a high-refractive index layer (not illustrated in the figure). The low-refractive index layer is, for example, constituted of a p-type Alₓ₆Ga₁₋ₓ₆As (0<x6<1) with a thickness of λ₀/4n₃ (n₃ is the refractive index). The high-refractive index layer is, for example, constituted of a p-type Alₓ₇Ga₁₋ₓ₇As (0<x7<x6) with a thickness of λ₀/4n₄ (n₄ is the refractive index). The contact layer 16 is, for example, constituted of a p-type Alₓ₈Ga₁₋ₓ₈As (0<x8<1).

In the laser diode 1, for example, a current confining layer 18 is provided in the upper DBR layer 15. In this embodiment, the current confining layer 18 corresponds to a specific example of “oxide confined layer” of the present invention. The current confining layer 18 is provided in substitution for the low-refractive index layer, for example, in a portion of the refractive index layer several layers away from the active layer 13 side in the upper DBR layer 15. The current confining layer 18 includes the current injection region 18A and a current confining region 18B. The current injection region 18A is formed in middle of the plane. The current confining region 18B is formed in the surrounding of the current injection region 18A, that is, in an outer edge region of the current confining layer 18. In this embodiment, the current injection region 18A corresponds to a specific example of “unoxidized region” of the present invention.

The current injection region 18A is, for example, formed of a p-type Alₓ₉Ga₁₋ₓ₉As (0<x9≦1). The current confining region 18B contains, for example, an aluminum oxide (Al₂O₃), and is obtained by oxidizing highly-concentrated Al contained in an oxidized layer 18D from its side face, as will be described later. Thereby, the current confining layer 18 has a function of confining the current. For example, the current confining layer 18 may be formed inside the upper spacer layer 14, or may be formed between the upper spacer layer 14 and the upper DBR layer 15.

A plurality of upper electrodes 31 are formed in regions on the top face of the mesa 17 (the top face of the contact layer 16) not facing the current injection region 18A. A lower electrode 32 is provided on the rear face of the substrate 10. In this embodiment, the upper electrode 31 corresponds to a specific example of “metal electrode” of the present invention. A pedestal 33 in contact with the side face of the mesa 17, and burying the mesa 17 except the top face of the mesa 17 is provided. Further, an insulating layer 34 is formed on the top face of the pedestal 33, and on the surface of the top face of the mesa 17 not in contact with the upper electrode 31. An electrode pad 35 bonding a wiring (not illustrated in the figure), and a wiring layer 36 are provided on the surface of the insulating layer 34 corresponding to immediately above the pedestal 33. The electrode pad 35 and the upper electrode 31 are electrically connected to each other through the wiring layer 36.

Here, the upper electrode 31, the electrode pad 35, and the wiring layer 36 are, for example, constituted by stacking titanium (Ti), platinum (Pt), and gold (Au) in this order, and are electrically connected to the contact layer 16 in the upper part of the mesa 17. The lower electrode 32 has, for example, a structure in which an alloy of gold (Au) and germanium (Ge), nickel (Ni), and gold (Au) are stacked in this order from the substrate 10 side, and is electrically connected to the substrate 10. The pedestal 33 is, for example, formed of an insulating resin such as polyimide. The insulating layer 34 is, for example, formed of an insulating material such as an oxide and a nitride.

Next, with reference to FIG. 1A, the shape and the size of the mesa 17 and the current injection region 18A, and arrangement of the plurality of upper electrodes 31 will be described.

In this embodiment, the cross-sectional shape of the columnar mesa 17 in the plane direction is different from the cross-sectional shape of the current injection region 18A in the plane direction. Specifically, the cross-sectional shape of the mesa 17 in the plan direction is circular, while the cross-sectional shape of the current injection region 18A in the plane direction is rectangular. Further, in this embodiment, where the maximum diameter of the current injection region 18A is R1, and the diameter of the mesa 17 is R2, R1 and R2 satisfy R1/R2>0.5. The diameter R2 of the mesa 17 has a scale further smaller than the minimum scale (for example, 20 μm) of the present situation, and is 18 μm, for example. When the diameter R2 of the mesa 17 is, for example, 18 μm, the maximum diameter R1 of the current injection region 18A is 10 μm, and R1 and R2 have the relationship of R1/R2=0.56>0.5.

The minimum scale of the present situation exemplified above indicates the minimum scale of the mesa formed by trial manufacture or the like by the applicant in the past, and does not indicate the minimum scale of the mesa of the VCSEL which has been launched. In this manner, in this embodiment, because the diameter R2 of the mesa 17 is small, close to half the region on the top face of the mesa 17 is the region facing the current injection region 18A, and the region on the top face of the mesa 17 not facing the current injection region 18A is substantially divided into a plurality of regions.

This means that when it is assumed that a ring electrode (not illustrated in the figure) is provided on the top face of the mesa 17, the diameter R2 of the mesa 17 is small to the degree that the ring electrode easily covers at least one of four corners “a” of the region facing the current injection region 18A, due to influence of a position shift of the ring electrode during the manufacturing process. For example, when the maximum diameter R1 of the current injection region 18A is 10 μm, the width W of the ring electrode is 1 μm, and the position accuracy ΔD of the ring electrode is ±2 μm, it can be seen from the following formula that the diameter R2 of the mesa 17 is necessarily 20 μm at a minimum. Therefore, in the case where the diameter R2 of the mesa 17 is 18 μm, the diameter R2 of the mesa 17 is in 2 μm short from the minimum necessary size of the diameter R2 of the mesa 17.

R2=R1+W×2+(ΔD+ΔD)×2=10+1×2+(2+2)×2=20 μm

In this embodiment, it is possible to provide the electrode on the top face of the mesa 17 without depending on improvement of the position accuracy of the electrode formed on the top face of the mesa 17, even in the case where the diameter R2 of the mesa 17 has a small value as described above. Specifically, as described above, the plurality of upper electrodes 31 are formed in the regions (empty spaces) of the top face of the mesa 17 not facing the current injection region 18A.

Each upper electrode 31 has a shape corresponding to the shape of the region on the top face of the mesa 17 not facing the current injection region 18A. Each upper electrode 31 has a shape surrounded by an arcuate and a chord, for example as illustrated in FIG. 1B.

When the gravity point (center) (not illustrated in the figure) of the plurality of upper electrodes 31 in the plane, and the gravity point (center) (not illustrated in the figure) of the current injection region 18A in the plane are superposed on each other in the same plane, a gap D1 between an edge (inner edge) of each upper electrode 31, and an edge of the current injection region 18A is uniform. Further, when the middle point (not illustrated in the figure) of the top face of the mesa 17 in the plane, and the gravity point (center) of the plurality of upper electrodes 31 in the plane are superposed on each other in the same plane, a gap D2 between an edge of the top face of the mesa 17, and an edge (outer edge) of each upper electrode 31 is uniform. That is, each upper electrode 31 is point-symmetrically arranged around the gravity point (center) of the plurality of upper electrodes 31 in the plane.

FIG. 1B exemplifies a layout of the case where the gravity point (center) of the plurality of upper electrodes 31 in the plane, the gravity point (center) of the current injection region 18A in the plane, and the middle point of the top face of the mesa 17 in the plane coincide with each other in the same plane. Therefore, there is actually a case that the gravity point (center) of the plurality of upper electrodes 31 in the plane is slightly shifted from the gravity point (center) of the current injection region 18A in the plane, and from the middle point of the top face of the mesa 17 in the plane due to the position shift generated when the plurality of upper electrodes 31 are formed on the top face of the mesa 17. Further, there is a case that the gravity point (center) of the current injection region 18A in the plane is slightly shifted from the middle point of the top face of the mesa 17 in the plane due to manufacturing error generated when the current injection region 18A is formed.

### Manufacturing Method

The laser diode 1 of this embodiment can be manufactured, for example, as will be described next.

FIGS. 3 to 6 illustrate a manufacturing method of the laser diode 1 in a process order. FIGS. 3 to 6 illustrate an example of the structure of the cross-section obtained by cutting an element during the manufacturing process in a position corresponding to arrow line B-B of FIG. 1, respectively.

Here, a compound semiconductor layer on the substrate 10 of GaAs is formed by, for example, MOCVD (metal organic chemical vapor deposition). At this time, trimethylaluminum (TMA), trimethylgallium (TMG), trimethylindium (TMIn), or arsine (AsH₃) is, for example, used as a material of a group III-V compound semiconductor, H₂Se is, for example, used as a material of a donor impurity, and dimethylzinc (DMZ) is, for example, used as a material of an acceptor impurity.

Specifically, first, the lower DBR layer 11, the lower spacer layer 12, the active layer 13, the upper spacer layer 14, the upper DBR layer 15, and the contact layer 16 are stacked in this order on the substrate 10 (FIG. 3). At this time, the oxidized layer 18D is formed in part of the upper DBR layer 15. The oxidized layer 18D is a layer to be the current confining layer 18 by being oxidized in an oxidizing process which will be describe later, and contains, for example, AlAs.

Next, after the contact layer 16 is etched in a predetermined shape, a circular resist layer (not illustrated in the figure) is formed on the surface of the contact layer 16. Next, the layers from the contact layer 16 to the upper part of the lower DBR layer 11 are selectively etched, for example, by reactive ion etching (RIE) by using the resist layer as a mask. Thereby, the mesa 17 is formed immediately below the circular resist layer (not illustrated in the figure) (FIG. 4). At this time, the oxidized layer 18D is exposed to the side face of the mesa 17. After that, the resist layer is removed.

Next, the oxidizing process is performed in a water-vapor atmosphere at a high-temperature, and Al contained in the oxidized layer 18D is selectively oxidized from the side face of the mesa 17. Thereby, the outer edge region of the oxidized layer 18D becomes the insulating layer (aluminum oxide) in the mesa 17, and the current confining layer 18 is formed (FIG. 5).

Next, after the pedestal 33 made of an insulating resin such as polyimide is formed in the surrounding of the mesa 17, the insulating layer 34 made of an insulating inorganic material such as a silicon oxide (SiO₂) is formed on the whole surface (FIG. 6). Next, after the resist layer (not illustrated in the figure) having an aperture in the region on the top face of the mesa 17, in which the plurality of upper electrodes 31 are formed in the subsequent step, is formed, the insulating layer 34 is selectively removed, for example, by RIE by using the resist layer as a mask. Thereby, an aperture (not illustrated in the figure) is formed in a portion in which the upper electrode 31 is formed.

Next, the above-described metal material is stacked on the whole surface, for example, by vacuum evaporation. After that, unnecessary metal materials are removed together with the resist layer, for example, by lift-off. Thereby, the plurality of upper electrodes 31 are formed in the regions on the top face of the mesa 17 not facing the current injection region 18A. In the same manner, the electrode pad 35 and the wiring layer 36 are formed on the insulating layer 34 immediately above the pedestal 33. Further, after the rear face of the substrate 10 is appropriately polished to adjust its thickness, the lower electrode 32 is formed on the rear face of the substrate 10 (refer to FIG. 1). In this manner, the laser diode 1 of this embodiment is manufactured.

Next, operations and effects of the laser diode 1 of this embodiment will be described.

### Operations and Effects

In the laser diode 1 of this embodiment, when a predetermined voltage is applied between the lower electrode 32 and the upper electrode 31, a current is injected into the active layer 13 through the current injection region 18A in the current confining layer 18, and light emission is thereby generated by recombination of electrons and holes. This light is reflected at the pair of the lower DBR layer 11 and the upper DBR layer 15, and the laser oscillation is generated at a predetermine wavelength. As a result, for example, a right circular beam is emitted outside from the top face of the mesa 17.

Typically, it is necessary to make the parasitic capacity of the laser diode small to modulate the laser diode at high speed. In the VCSEL, for example, it is possible to suppress the capacity of the current confining layer and the p-n junction low by making the mesa diameter small. However, the mesa diameter is limited by the size (width) and the position accuracy of the electrode formed on the top face of the mesa.

For example, one solution to the limitation according to the position accuracy is that the current confining layer is increased in thickness or multilayered, as described in Japanese Unexamined Patent Publication No. 2003-168845. By making the current confining layer thick or multilayered, it is possible to insulate the side face of the mesa. As a result, it is actually possible to reduce the diameter of the mesa. However, when the current confining layer is increased in thickness, high strain stress is generated inside the mesa, and there is a risk that reliability of a device is lost. Further, in the case where the current confining layer is multilayered, the oxidation rate of each layer is not easily controlled, and there is an issue that it is not easy to manufacture an intended structure.

Meanwhile, in this embodiment, the plurality of upper electrodes 31 are provided in the regions on the top face of the mesa 17 not facing the current injection region 18A. Thereby, the diameter of the mesa 17 having the cross-sectional shape different from the cross-sectional shape of the current injection region 18A is reduced. As a result, in the case where the region on the top face of the mesa 17 not facing the current injection region 18A is substantially partitioned into the plurality of regions (refer to FIG. 1), it is possible to arrange each upper electrode 31 in that region (empty space), even if the position accuracy of the upper electrode 31 is the same as that of related art. As a result, it is possible to make the diameter R2 of the mesa 17 smaller compared with the case where a single electrode is provided on the top face of the mesa 17. Further, the reliability of the device is not lost, because the plurality of upper electrodes 31 are provided on the top face of the mesa 17. Accordingly, in this embodiment, it is possible to make the diameter R2 of the mesa 17 smaller without use of a method which loses the reliability of the device, and is not easily controlled.

For example, if the diameter R2 of the mesa 17 is set to 18 μm in this embodiment when the minimum scale of the present situation is 20 μm, the cross-sectional area of the mesa 17 in the plane direction is approximately 80% of the cross-sectional area of the mesa with a diameter of 20 μm in the plane direction, and the parasitic capacity of the mesa 17 is also approximately 80% of the parasitic capacity of the mesa with the diameter of 20 μm. Thus, in the laser diode 1 of this embodiment, the operation at higher speed is possible compared with that of related art.

### Modification

In the above-described embodiment, although the case in which the cross-sectional shape of the mesa 17 in the plane direction is circular, and the cross-sectional shape of the current injection region 18A in the plane direction is rectangular has been exemplified, inversely, the cross-sectional shape of the mesa 17 in the plane direction may be rectangular, and the cross-sectional shape of the current injection region 18A in the plane direction may be circular, for example, as illustrated in FIGS. 7A and 7B. At this time, where the length of one side of the mesa 17 is L, and the diameter of the current injection region 18A is R3, L and R3 satisfy R3/L>0.5. Further, the length L of the one side of the mesa 17 has a scale further smaller than the minimum scale (for example, 20 μm) of the present situation, and is, for example, 18 μm. For example, when the length L of the one side of the mesa 17 is 18 μm, the diameter R3 of the current injection region 18A is 10 μm, and R1 and R2 have the relationship of R3/L=0.56>0.5.

Like the above-described embodiment, the minimum scale of the present situation exemplified above indicates the minimum scale of the mesa formed by trial manufacture or the like by the applicant in the past, and does not indicate the minimum scale of the mesa of the VCSEL which has been launched. In this manner, in this modification, because the length L of the one side of the mesa 17 is small, close to half the region on the top face of the mesa 17 is the region facing the current injection region 18A, and the region on the top face of the mesa 17 not facing the current injection region 18A is substantially partitioned into the plurality of regions.

In this modification, it is possible to provide the electrode on the top face of the mesa 17 without depending on the improvement of the position accuracy of the electrode formed on the top face of the mesa 17, even in the case where the length L of the one side of the mesa 17 has the small value as described above. Specifically, the plurality of upper electrodes 31 are formed in the regions (empty spaces) on the top face of the mesa 17 not facing the current injection region 18A, as described above.

Each upper electrode 31 has a shape corresponding to the shape of the region on the top face of the mesa 17 not facing the current injection region 18A. In this modification, each upper electrode 31 has, for example, a shape surrounded by right angled isosceles and a chord, as illustrated in FIG. 7B.

Also in this modification, when the gravity point (center) (not illustrated in the figure) of the plurality of the upper electrodes 31 in the plane, and the gravity point (center) (not illustrated in the figure) of the current injection region 18A in the plane are superposed on each other in the same plane, the gap D1 between the edge (inner edge) of each upper electrode 31, and the edge of the current injection region 18A is uniform. Further, when the middle point (not illustrated in the figure) of the top face of the mesa 17 in the plane, and the gravity point (center) of the plurality of upper electrodes 31 in the plane are superposed on each other, the gap D2 between the edge of the top face of the mesa 17, and the edge (outer edge) of each upper electrode 31 is uniform. That is, each upper electrode 31 is point-symmetrically arranged around the gravity point (center) of the plurality of upper electrodes 31 in the plane.

FIG. 7B exemplifies an layout of the case where the gravity point (center) of the plurality of upper electrodes 31 in the plane, the gravity point (center) of the current injection region 18A in the plane, and the middle point of the top face of the mesa 17 in the plane coincide with each other in the same plane. Therefore, there is actually a case that the gravity point (center) of the plurality of upper electrodes 31 in the plane is slightly shifted from the gravity point (center) of the current injection region 18A in the plane, and from the middle point of the top face of the mesa 17 in the plane due to the position shift generated when the plurality of upper electrodes 31 are formed on the top face of the mesa 17. Further, there is a case that the gravity point (center) of the current injection region 18A in the plane is slightly shifted from the middle point of the top face of the mesa 17 in the plane due to manufacturing error generated when the current injection region 18A is formed.

Also in this modification, the plurality of upper electrodes 31 are provided in the regions on the top face of the mesa 17 not facing the current injection region 18A. Thereby, the length L of the one side of the mesa 17 having the cross-sectional shape different from the cross-sectional shape of the current injection region 18A is reduced. As a result, in the case where the region on the top face of the mesa 17 not facing the current injection region 18A is substantially partitioned into the plurality of regions (refer to FIG. 7B), it is possible to arrange each upper electrode 31 in that region (empty space), even if the position accuracy of the upper electrode 31 is the same as that of related art. As a result, it is possible to make the length L of the one side of the mesa 17 smaller compared with the case where a single electrode is provided on the top face of the mesa 17. Further, the reliability of the element is not lost, because the plurality of upper electrodes 31 are provided on the top face of the mesa 17. Accordingly, in this embodiment, it is possible to make the length L of the one side of the mesa 17 smaller without use of a method which loses the reliability of the device, and is not easily controlled.

Hereinbefore, although the present invention has been described with the embodiment and the modification, the present invention is not limited to the above-described embodiment and the like, and various modifications may be made.

For example, in the above-described embodiment and the like, the upper electrodes 31 are connected to each other, and may be regarded as one electrode. For example, as illustrated in FIGS. 8 and 9, the single upper electrode 31 may be formed over the whole region (empty space) on the top face of the mesa 17 not facing the current injection region 18A. Even in this case, when the gravity point (center) (not illustrated in the figure) of the single upper electrode 31 in the plane, and the gravity point (center) (not illustrated in the figure) of the current injection region 18A in the plane are superposed on each other in the same plane, the gap D1 between the edge (inner edge) of the single upper electrode 31, and the edge of the current injection region 18A is uniform. Further, when the middle point (not illustrated in the figure) of the top face of the mesa 17 in the plane, and the gravity point (center) of the single upper electrode 31 in the plane are superposed on each other in the same plane, the gap D2 between the edge of the top face of the mesa 17, and the edge (outer edge) of the single upper electrode 31 is uniform. That is, the single upper electrode 31 is point-symmetrically arranged around the gravity point (center) of the single upper electrode 31 in the plane.

In addition, in the case where the single upper electrode 31 has a shape illustrated in FIG. 8, the position in the single upper electrode 31 adjacent to a corner portion “b” of the current injection region 18A looks like a notch. Further, although not illustrated in the figure, a notch may be provided in the position in the single upper electrode 31 adjacent to the corner portion “b” of the current injection region 18A. In this case, it is possible to reduce the risk that the single upper electrode 31 covers the corner portion “b” of the current injection region 18A due to the position shift or the like.

Also at this time, R1 and R2 satisfy R1/R2>0.5. The diameter R2 of the mesa 17 has a scale further smaller than the minimum scale (for example, 20 μm) of the present situation, and is, for example, 18 μm. For example, when the diameter R2 of the mesa 17 is 18 μm, the maximum diameter R1 of the current injection region 18A is 10 μm, and R1 and R2 have the relationship of R1/R2=0.56>0.5.

The present application contains subject matter related to that disclosed in Japanese Priority Patent Application JP 2010-089841 filed in the Japan Patent Office on Apr. 8, 2010, the entire contents of which is hereby incorporated by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A laser diode comprising:
a columnar mesa including a first multilayer film reflecting mirror, an active layer, and a second multilayer film reflecting mirror in this order, including an oxide confined layer having an unoxidized region in middle of a plane, and having a cross-sectional shape in a plane direction different from a cross-sectional shape of the unoxidized region in a plane direction; and
a plurality of metal electrodes formed in regions on a top face of the mesa not facing the unoxidized region.

2. The laser diode according to claim 1, wherein when a gravity point (center) of the plurality of metal electrodes in a plane, and a gravity point (center) of the unoxidized region in a plane are superposed on each other in a same plane, a gap between an edge of each metal electrode, and an edge of the unoxidized region is uniform.

3. The laser diode according to claim 1, wherein each metal electrode has a shape corresponding to a shape of the region on the top face of the mesa not facing the unoxidized region.

4. The laser diode according to claim 3, wherein each metal electrode is point-symmetrically arranged around the gravity point (center) of the plurality of metal electrodes in the plane.

5. The laser diode according to claim 1, wherein the cross-sectional shape of the mesa in the plan direction is circular, and the cross-sectional shape of the unoxidized region in the plane direction is rectangular.

6. The laser diode according to claim 5, wherein R1 and R2 satisfy the following formula,
R1/R2>0.5
where a maximum diameter of the unoxidized region is R1, and a diameter of the mesa is R2.

7. The laser diode according to claim 1, wherein the cross-sectional shape of the mesa in the plan direction is rectangular, and the cross-sectional shape of the unoxidized region in the plane direction is circular.

8. The laser diode according to claim 7, wherein L and R3 satisfy the following formula,
R3/L>0.5
where a length of one side of the mesa is L, and a diameter of the unoxidized region is R3.

9. The laser diode according to claim 1, further comprising:
a pedestal formed in contact with a side face of the mesa;
a wiring layer formed on the pedestal, and electrically connected to each metal electrode; and
a pad electrode electrically connected to the wiring layer.

10. A laser diode comprising:
a columnar mesa including a first multilayer film reflecting mirror, an active layer, and a second multilayer film reflecting mirror in this order, including an oxide confined layer having an unoxidized region in middle of a plane, and having a cross-sectional shape in a plane direction different from a cross-sectional shape of the unoxidized region in a plane direction; and
a circular metal electrode formed in a region on a top face of the mesa not facing the unoxidized region,
wherein when a gravity point (center) of the metal electrode in a plane, and a gravity point (center) of the unoxidized region in a plane are superposed on each other in a same plane, a gap between an edge of the metal electrode, and an edge of the unoxidized region is uniform.

11. The laser diode according to claim 10, wherein
the cross-sectional shape of the mesa in the plan direction is circular, and the cross-sectional shape of the unoxidized region in the plane direction is rectangular, and
the metal electrode includes a notch in a portion corresponding to a corner of the unoxidized region.

12. The laser diode according to claim 11, wherein R1 and R2 satisfy the following formula,
R1/R2>0.5
where a diameter of the mesa is R1, and a maximum diameter of the unoxidized region is R2.
